(19) United States
(12) Patent Application Publication
(10) Pub. No.: US 2006/0046337 A1
(43) Pub. Date: Mar. 2, 2006

(54) Metalized plastic seal

(75) Inventor: Stephen R. Shiffer, Pearl City, IL (US)

Correspondence Address: Kris T. Fredrick;Honeywell International, Inc., 101 Columbia Rd., P.O. Box 2245, Morristown, NJ, 07962, US

(73) Assignee: Honeywell International Inc.

(21) Appl. No.: 10/933,038

(22) Filed: Sep. 2, 2004

(51) Int. Cl. H01L 21/00

(52) U.S. Cl. 438/51; 438/55; 438/64

(57) ABSTRACT

Packaging assembly methods and systems are disclosed. In general, a substrate can be provided upon which one or more sensing components can be configured and located. The substrate and the sensing components can then be sealed with a metalized plastic cover and a metalized plastic base in order to provide a barrier, which prevents moisture from migrating through the metalized plastic cover and the metalized plastic base and damaging the substrate and sensing components. Sealing may be implemented by soldering the metalized plastic cover to the metalized plastic base to provide a hermitically sealed barrier and EMC protection to said sensing components.

### TECHNICAL FIELD

Embodiments are generally related to integrated circuit manufacturing and assembly processes, including the packaging of electrical components. Embodiments are also related to sensors and sensor components. Embodiments are also related to the use of metalized plastic material.

### BACKGROUND OF THE INVENTION

Sensing components utilized in sensor applications are often sealed by metal and glass. Metal and glass can only accomplish the sealing of sensor and electronic switching components thereof in a hermetic environment. An important feature of a sensor application is the ability for the sensor device or system to survive in hostile and/or harsh environments, such as, for example, within or near an automobile tire under analysis by a sensing device. Thermoplastic and thermoset materials have been utilized for sealing, but such materials are not hermetic and generally allow moisture to migrate to internal components. Of these two types of plastics, thermoplastic is worse in its sealing capabilities because from a pure material standpoint, components within the sensing package thereof are difficult to bond.

The use of plastic does allow complex configurations to be created from inexpensive materials. As explained above, however, a tradeoff exists, because the use of such inexpensive plastic material can result in moisture damage to sensing components surrounded by such plastic material. It is believed that the metallization of plastic can provide a barrier for preventing the migration of moisture and fluids through the plastic. To date, however, metalized plastic has not been utilized successfully in sensor manufacturing processes.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide for an improved packaging assembly method and system.

It is another aspect of the present invention to provide for packaging assembly methods and systems involving the use of metalized plastic cover and base portions, which prevent moisture from coming into contact with sensing and other electronic components sealed by such cover and base portions.

The aforementioned aspects of the invention and other objectives and advantages can now be achieved as described herein. Packaging assembly methods and system are disclosed. In general, a substrate can be provided upon which one or more sensing components can be configured and located. The substrate and the sensing components can then be sealed with a metalized plastic cover and a metalized plastic base in order to provide a barrier, which prevents moisture from migrating through the metalized plastic cover and the metalized plastic base and damaging the substrate and sensing components. Sealing may be implemented by soldering the metalized plastic cover to the metalized plastic base to provide a hermitically sealed barrier.

The metalized plastic cover and base may be configured by providing a plastic material and plating such plastic material with metal. In an automotive design, for example, the cover or “cap” portion could be soldered into position to thereby provide a hermetic connection between the metalized plastic cover or cap and the metalized plastic base. Soldering, of course, is not required, but is merely one method for providing a hermitic seal.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a side view of a sensor system, which can be implemented in accordance with one embodiment of the present invention;

FIG. 2 illustrates a top view of the sensor system depicted in FIG. 1 in accordance with one embodiment of the present invention;

FIG. 3 illustrates a bottom view of the sensor system depicted in FIGS. 1-2 in accordance with one embodiment of the present invention;

FIG. 4 illustrates a flow chart of operations depicting general manufacturing process steps that may be followed in order to implement a sensor system, in accordance with one embodiment of the present invention;

FIG. 5 illustrates a side-perspective view of a sensor system, which can be implemented in accordance with a preferred embodiment of the present invention;

FIG. 6 illustrates a side view of the sensor system depicted in FIG. 5 in accordance with a preferred embodiment of the present invention; and

FIG. 7 illustrates a vertical view of a sensor body, which is adapted for use with the sensor system depicted in FIGS. 5-6, in accordance with a preferred embodiment of the present invention.

### DETAILED DESCRIPTION OF THE INVENTION

The particular values and configurations discussed in these non-limiting examples can be varied and are cited merely to illustrate at least one embodiment of the present invention and are not intended to limit the scope of the invention.

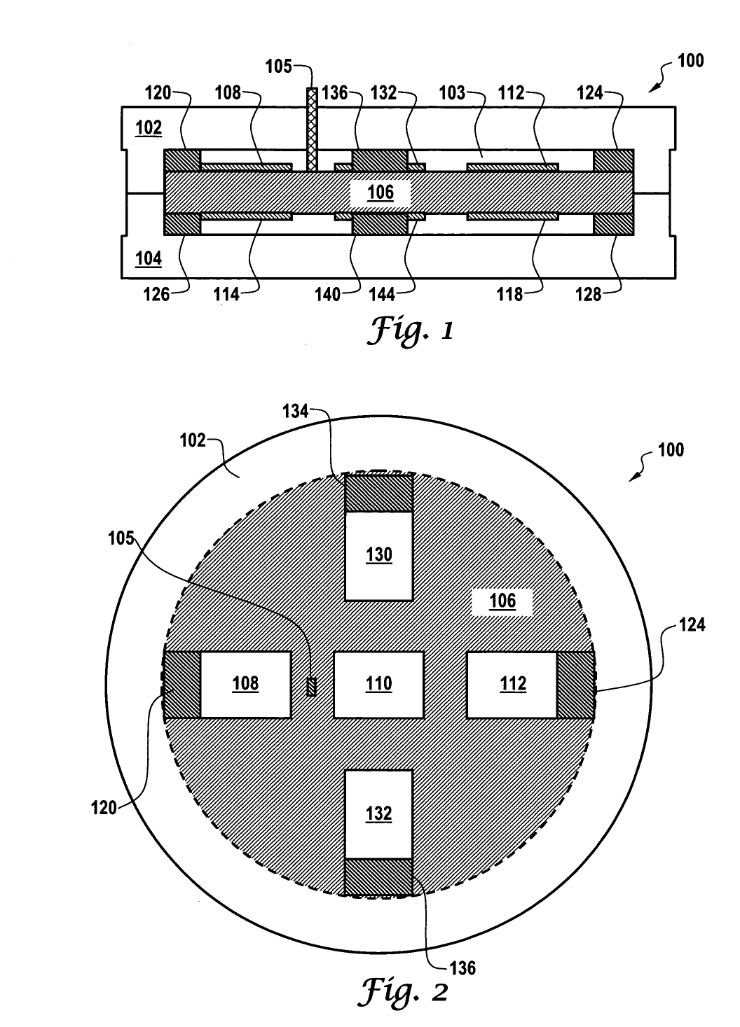

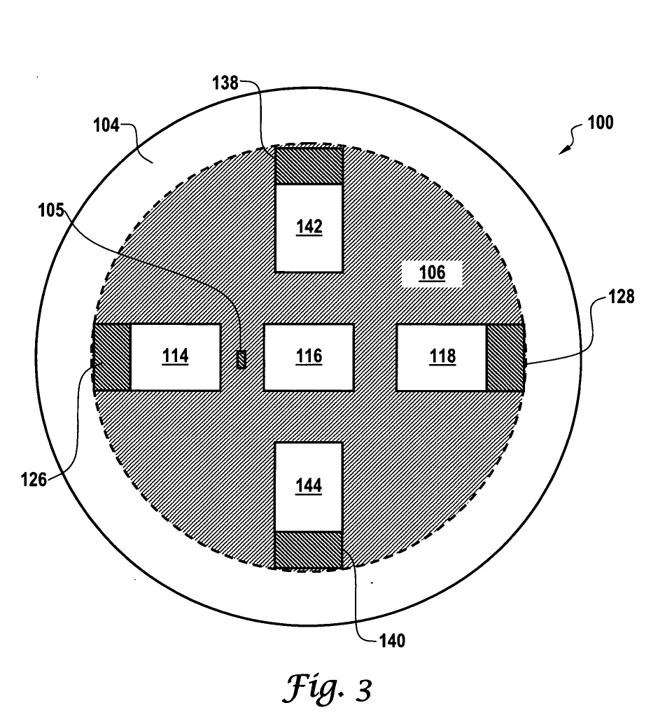

FIG. 1 illustrates a side view of a sensor system 100, which can be implemented in accordance with one embodiment of the present invention. FIG. 2 illustrates a top view of the sensor system 100 depicted in FIG. 1 in accordance with one embodiment of the present invention. FIG. 3 illustrates a bottom view of the sensor system 100 depicted in FIGS. 1-2 in accordance with one embodiment of the present invention. Note that in FIGS. 1-3, identical parts or elements are generally indicated by identical reference numerals.

System 100 generally includes a substrate 106 upon which one or more sensing components 108, 110, 112, 114, 116, 118, 130, 132, 142 and 144 can be configured and/or located. Substrate 106 and sensing components 108, 110, 112, 114, 116, 118, 130, 132, 142 and 144 can then be sealed with a metalized plastic cover 102 and a metalized plastic base 104 in order to provide a barrier, which prevents moisture from migrating through the metalized plastic cover 102 and the metalized plastic base 104 and damaging the substrate 106 and sensing components 108, 110, 112, 114, 116, 118, 130, 132, 142 and 144. Metalized plastic base 104 and/or metalized plastic cover 102 can also be configured to provide enhanced EMC (electromagnetic compatibility) protection. To provide EMCH protection, metalized plastic base 104 and/or metalized plastic cover 102 can be formed from any material that provides EMC protection. In general, electromagnetic compatibility (EMC) can be considered the ability of an electrical component to operate satisfactorily in its electromagnetic environment without influencing this environment (in any undue manner), to which other units may belong.

Sensing components 108, 110, 112, 114, 116, 118, 130, 132, 142 and 144 can communicate with one another via discrete electronic circuitry located on substrate 106, but not shown in FIGS. 1-3. Such electronic circuitry and sensing components 108, 110, 112, 114, 116, 118, 130, 132, 142 and 144 can also communicate and interact with an antenna 105 which can protrude through cover 102 in order to send and receive wireless data via radio frequency communication. Thus, sensing data collected by sensing components 108, 110, 112, 114, 116, 118, 130, 132, 142 and 144 can be transmitted to external receivers for further analysis.

Metalized plastic cover 102 and base 104 can be configured in a circular shape. It can be appreciated, however, that cover 102 and base 104 can be configured in a number of different shapes, such as rectangular, square, triangular, and so forth, depending upon design considerations. The shape of cover 102 and base 104 are thus described in the context of a circular shape with respect to one embodiment. Other shapes can be implemented, however, in accordance with alternative embodiments. A plurality of support stops 120, 123, 134, 136 and 126, 128, 138, 140 can also be included with system 100 in order to provide support to substrate 106 and insure a proper fit within a gap 103 formed between metalized plastic cover 102 and metalized plastic base 104.

In one embodiment, sealing may be implemented by soldering the metalized plastic cover 102 to the metalized plastic base 104 to provide a hermitically sealed barrier. The metalized plastic cover 102 and base 104 may be formed by providing a plastic material and plating such plastic material with metal.

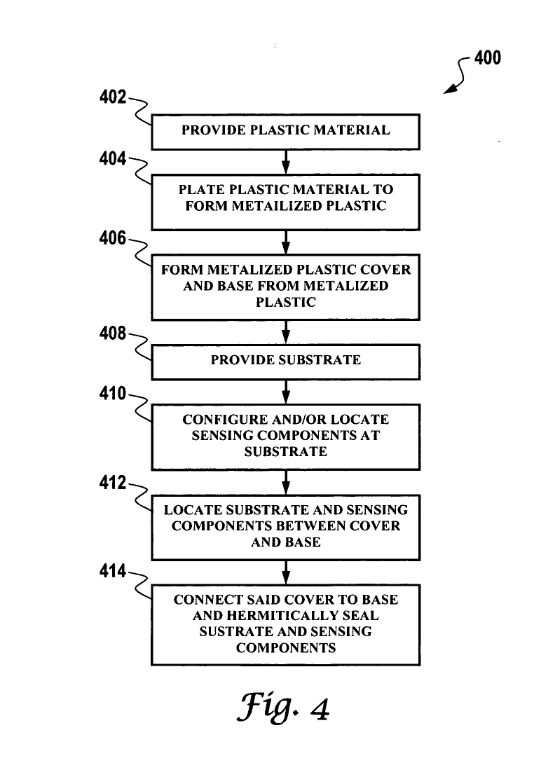

FIG. 4 illustrates a flow chart 400 of operations depicting general manufacturing process steps that may be followed in order to implement a sensor system, in accordance with one embodiment of the present invention. As depicted at block 402, a plastic material can be provided. Thereafter, as indicated at block 404, the plastic material may be plated with a metal in order to form a metalized plastic material. Next, as indicated at block 406, a metalized plastic cover and a metalized plastic base such as cover 102 and base 104 of FIGS. 1-3 can be formed from the metalized plastic.

Thereafter, as depicted at block 408, a substrate such as substrate 106 of FIGS. 1-3 can be provided. Next, as indicated at block 410, sensing components such as sensing components 108, 110, 112, 114, 116, 118, 130, 132, 142 and 144 depicted in FIGS. 1-3 can be configured from and/or located on the substrate. Thereafter, as indicated at block 412, the substrate and the sensing components can be located between the metalized plastic cover and base. Finally, as indicated at block 414, the metalized plastic cover and base can be connected to one another to provide a hermetic seal about the substrate and sensing components.

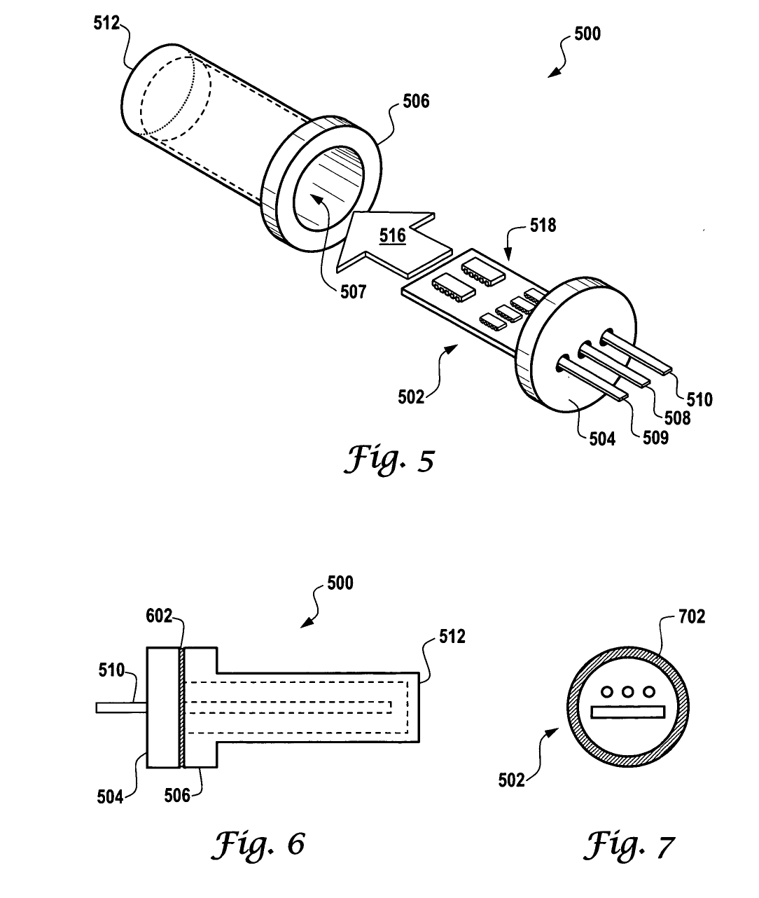

FIG. 5 illustrates a side-perspective view of a sensor or packaging assembly system 500, which can be implemented in accordance with a preferred embodiment of the present invention. FIG. 6 illustrates a side view of the packaging assembly system 500 depicted in FIG. 5 in accordance with a preferred embodiment of the present invention. Additionally, FIG. 7 illustrates a vertical view of a sensor 502 body, which is adapted for use with the packaging assembly system depicted in FIGS. 5-6, in accordance with a preferred embodiment of the present invention. Note that in FIGS. 5-7, identical or analogous parts are generally indicated by identical reference numerals.

System 500 generally includes a sensor body 502 or substrate upon which one or more sensing components 518 can be configured. A metalized plastic cover 506 can be implemented in accordance with a metalized plastic base 504 for sealing the sensor body 502 or substrate and one or more of the sensing components 518 therebetween in order to provide a barrier, which prevents moisture from migrating through the metalized plastic cover 506 and the metalized plastic base 504. The metalized plastic cover 506 is soldered to the metalized plastic base 504 via a solder 602 to provide such a barrier. Note that cover 506 can be connected to and/or integrated with a cap portion 512, which is also formed from metalized plastic. The sensing components 518 are therefore disposed within cap 512.

Arrow 516 in FIG. 5 generally indicates how base 504 is inserted into cap 512 through an opening 507 in cover 506. Note that a plurality of connectors 509, 508, 510 extend from base 504. In FIG. 7, a metallization 702 is shown with respect to a vertical view of the sensor body 502. In general, system 500 permits electronic components, such as, for example, components 518, to be sealed by providing a true metal-to-metal seal using metalized plastic and a solder 602 between metal configured upon the plastic. The components 518 are therefore hermetically sealed, while also provided with EMC protection due to the presence of such a metal-to-metal seal. Thus, such a solder seal permits the implementation of flexible components 518, which can be molded to a desired output.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered.

The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

The embodiments of the invention in which an exclusive property or right is claimed are defined as follows.

Having thus described the invention what is claimed is:

1. A packaging assembly method, comprising the steps of:
providing a substrate upon which at least one sensing component is configured;
sealing said substrate and said at least one sensing component between a metalized plastic cover and a metalized plastic base in order to provide a barrier, which prevents moisture from migrating through said metalized plastic cover and said metalized plastic base.

2. The method of claim 1 wherein the step of sealing said substrate and said at least one sensing component with a metalized plastic cover and a metalized plastic base further comprises the step of:
soldering said metalized plastic cover to said metalized plastic base to provide barrier thereof.

3. The method of claim 2 wherein said barrier comprises a hermetic seal.

4. The method of claim 1 further comprising the steps of:
providing a plastic material; and
metalizing said plastic material to form said metalized plastic cover.

5. The method of claim 1 further comprising the steps of:
providing a plastic material; and
metalizing said plastic material to form said metalized plastic base.

6. The method of claim 1 further comprising the steps of:
providing a plastic material; and
plating said plastic material with metal to form said metalized plastic cover, wherein said metal and said plastic material provide EMC shielding.

7. The method of claim 1 further comprising the steps of:
providing a plastic material; and
plating said plastic material with metal to form said metalized plastic base, wherein said metal and said plastic material provide EMC shielding.

8. A packaging assembly system, comprising:
a substrate upon which at least one sensing component is configured; and
a metalized plastic cover and a metalized plastic base for sealing said substrate and said at least one sensing component therebetween in order to provide a barrier, which prevents moisture from migrating through said metalized plastic cover and said metalized plastic base.

9. The system of claim 8 said metalized plastic cover is soldered to said metalized plastic base to provide said barrier thereof.

10. The system of claim 9 wherein said barrier comprises a hermetic seal.

11. The system of claim 8 further comprising a plastic material, wherein said plastic material is metalized to form said metalized plastic cover.

14. The method of claim 8 further comprising a plastic material, wherein said plastic material is metalized to form said metalized plastic base.

15. The method of claim 8 further comprising a plastic material, wherein said plastic material is plated with metal to form said metalized plastic cover.

16. The method of claim 8 a plastic material, wherein said plastic material is plated with metal to form said metalized plastic base.

17. A packaging assembly system, comprising:
a substrate upon which at least one sensing component is configured;
a plastic material, wherein said plastic material is plated with metal to form a metalized plastic cover and a metalized plastic base for sealing said substrate and said at least one sensing component in order to provide a barrier, which prevents moisture from migrating through said metalized plastic cover and said metalized plastic base.

18. The system of claim 18 further comprising:
a cap portion composed of said plastic material, wherein said cap portion is associated with said metalized plastic cover; and
a sensor body formed from said substrate, wherein said sensor substrate is associated with said metalized plastic base and engages said cap portion through said cap portion through an opening configured from said metalized plastic cover.

19. The system of claim 18 further comprising a solder located between said metalized plastic base and said metalized plastic cover to provide a hermetic seal for hermetically sealing said at least one sensing component within said cap portion.

20. The system of claim 17 wherein said plastic material is plated with metal to form said metalized plastic base and said metalized cap, wherein said metal and said plastic material provide EMC shielding to said at least one sensing component hermetically sealed within said cap portion.
